(19) United States
(12) Patent Application Publication
(10) Pub. No.: US 2002/0119394 A1
(43) Pub. Date: Aug. 29, 2002

(54) Printing plate having a radiation-sensitive recording layer on a rolled and embossed aluminium support, and process for the production thereof

(76) Inventors: Gunter Hultzsch, Wiesbaden (DE); Klaus Joerg, Ingelheim (DE)

Correspondence Address: Ashley I. Pezzner, Esquire, CONNOLLY BOVE LODGE & HUTZ LLP, 1220 Market Street, P.O. Box 2207, Wilmington, DE, 19899, US

(21) Appl. No.: 10/020,103

(22) Filed: Dec. 14, 2001

(30) Foreign Application Priority Data
Dec. 23, 2000 (DE) 100 64 892.4

(51) Int. Cl. G03F 7/30; G03F 7/021; G03F 7/023

(52) U.S. Cl. 430/302; 430/165; 430/278.1; 430/157

(57) ABSTRACT

The printing plate comprises a rolled and embossed aluminium support whose surface has a coarse structure of pits, on which a fine structure of indents produced by electrochemical roughening is superimposed. The indents have a diameter of from 0.1 to 6 μm, and the average roughness Rₐ of the surface of the embossed aluminium support is in the range from 0.63 to 0.82 μm.

### FIELD OF THE INVENTION

The present invention relates to a printing plate having a radiation-sensitive recording layer on a rolled and embossed aluminium support which has a surface structure with pits which have an average diameter of from 10 to 60 μm, preferably from 20 to 24 μm, and to a process for the production thereof.

The first step in the production of planographic printing plates is usually imagewise exposure of the radiation-sensitive recording layer of the plate through a mask in a vacuum contact copy frame. The mask is brought into close contact with the recording layer as quickly as possible. After evacuation of the contact copy frame, no air bubbles should remain between the mask and the recording layer. Nitrogen liberated from the quinone diazide of the recording layer during exposure should also be transported away as quickly as possible so that no nitrogen bubbles form. Both requirements can be satisfied by a printing plate whose radiation-sensitive layer has been surface-roughened. A rough surface can be achieved, for example, by dusting before imagewise exposure. However, a process of this type usually produces unevenly roughened surfaces, with the consequence that uneven copy results are achieved using printing plates of this type.

The manufacturers of printing plates therefore provide their products with a surface of defined roughness. Various processes are used here. Thus, the printing plate support can be coated with a radiation-sensitive solution containing suspended water-soluble particles, which are washed out with water after the layer has been dried. The surface of the radiation-sensitive layer then has a multiplicity of indents.

It has been proposed to add to the coating solution for the recording layer a compound which eliminates gaseous nitrogen on heating to from 80 to 300° C. Nitroso, sulphonylhydrazine, azo or hydrazo compounds are particularly suitable. The elimination process commences during drying in the above-mentioned temperature range. In this way, the radiation-sensitive layer obtains a rough surface.

Finally, it has also been proposed to use a radiation-sensitive coating solution with a resin suspended therein which flocculates out and precipitates during drying and in this way roughens the surface structure. However, none of these processes has hitherto been able to establish itself.

A rough surface can also be achieved by application of continuous or interrupted matting layers. Thus, DE-A 30 09 928 (=GB-A 2,046,461) describes a process in which a light-sensitive layer is coated with a non-light-sensitive coating liquid which contains, in dispersed form, particles of polyethylene, polypropylene, ethylene-propylene copolymer, ethylene-vinyl acetate copolymer, polyethylene terephthalate or a crosslinked vinyl polymer. After the drying, the individual particles remain in the continuous top layer as very small projections.

Continuous or interrupted top layers having a defined surface roughness can be applied with the aid of an embossing roller. The coating solutions used for this purpose may comprise conventional matting agents, such as silicon dioxide, zinc oxide, titanium dioxide, glass beads, aluminium oxide, starch, poly(methyl methacrylate), polystyrene and phenolic resins (DE-A 26 06 793=GB-A 1,542,131).

Finally, matting can also be produced by dusting on a fine powder, which is melted onto the surface of the light-sensitive layer. To this end, the powder must have a lower softening point than the light-sensitive layer. The matting particles generally consist of polyvinyl acetate, polyvinylidene chloride, polyethylene oxide, polyethylene glycol, polyacrylic acid, polymethacrylic acid, polyacrylamide, polymethacrylamide, polybutyl acrylate, polystyrene, polyvinyl methyl ether, epoxy resins, phenolic resins, polyamides or polyvinylbutyral (DE-A 30 03 131=U.S. Pat. No. 4,288,521).

DE-A 31 31 570 (=GB-A 2 081 919) discloses a recording material having a light-sensitive layer and a matting layer located thereon. The matting layer is applied by spraying-on and drying an aqueous solution or dispersion comprising an organic copolymer. The spraying-on can also be carried out electrostatically. The radiation-sensitive layer may comprise a 1,2-naphthoquinone-2-diazide and a polymeric binder.

According to EP-A 0 344 985, the material which gives an interrupted matting layer is dissolved or dispersed in a hydrocarbon having a certain low conductivity and sprayed electrostatically onto the radiation-sensitive layer. The material used for the matting may also be light-sensitive. The advantage of this process is that the droplets hitting the layer have a substantially uniform size.

DE-A 34 33 247 (=U.S. Pat. No. 4,842,982) describes a radiation-sensitive recording material in which a rough top layer is sprayed onto the radiation-sensitive layer and dried. The two layers have essentially the same composition. If the recording material is exposed only briefly, as may be necessary for fine screen work, residues of the top layer frequently remain in the non-image areas after development. These then have to have been removed in an additional correction step.

Another way of producing a matted, light-sensitive recording material comprises introducing into the light-sensitive layer finely divided particles whose smallest dimension is at least as large as the thickness of the layer. The particles may be of an inorganic or organic nature (DE-A 29 26 236=AU-B 59 417/80). Thermally cured phenolic resins are described as particularly suitable (DE-A 31 17 702=GB-A 2 075 702).

JP-A 57-115 548 discloses a recording material whose radiation-sensitive layer comprises hydrophobic silicon dioxide particles having an average diameter of less than 500 μm and matting particles of polyethylene, polypropylene, ethylene-propylene copolymer or crosslinked vinyl polymers having an average diameter of from 3 to 40 μm. The silicon dioxide particles serve for dispersion of the matting particles.

A recording material in which the radiation-sensitive layer is itself matted offers on the one hand the advantage that, after imagewise exposure and subsequent development, the matting is retained at the image point. On the other hand, it is disadvantageous that undesired halation can occur around the matting particles in the radiation-sensitive layer. The matting particles may also form agglomerates, which impair the image quality of the prints.

The separate matting layers described are, on the other hand, soluble or dispersible in the developer and are removed virtually completely.

EP-0 649 063 describes a process in which an aqueous, anionically or anionically/nonionically stabilized dispersion of a resin which comprises up to 0.80 mmol of acid and/or salt groups per gram is sprayed onto a copy layer. This process has the disadvantage that excessively large droplets in the dispersion may result in development problems, and in addition the matting gives rise to an additional working step in the printing plate production process.

It is common to all these processes that a matting layer is applied to the radiation-sensitive layer or a matting agent is incorporated into the radiation-sensitive layer, where neither the matting layer nor the matting agent is firmly bonded to the support.

### OBJECT OF THE INVENTION

It is therefore an object of the present invention to provide a radiation-sensitive printing plate whose support has a fine surface structure of defined roughness and firm anchoring of the radiation-sensitive layer in the support material for a print run of greater than 150,000 prints without the disadvantages of the known materials, such as an additional matting layer or incorporation of a matting agent into the radiation-sensitive layer.

### SUMMARY OF THE INVENTION

This object is achieved by a printing plate of the type described at the outset in that a fine structure of indents with indent diameters in the range from 0.1 to 6 μm is superimposed on this surface structure.

The refinement of the printing plate arises from the features of claims 2 and 3.

A number of processes for the production of pre-embossed aluminium webs are described in the prior art. Under the name “pack rolling” (DE 28 32 580 C2, not claimed for printing plates), two aluminium webs are passed together between two rollers in the final rolling step. In the process, irregular, pre-roughened structures form on the sides facing away from the rollers, i.e. on the surfaces at which the first aluminium web comes into contact with the other aluminium web. This process has the disadvantage that the surface structure is too coarse and difficult to control for lithographic purposes. In addition, it exhibits significant direction orientation, which is unfavourable for the printing process.

For lithographic purposes, GB-A 93 307 454 (Alcan) describes a pre-roughening of this type for lithographic printing plates. This roughening has the same disadvantages as mentioned above.

In the lasertex process (WO 97/31 783 Alcoa), a steel roller into which indents have been burned by means of a laser is employed in the final rolling step. However, the structures obtained are coarse and are unsuitable for lithographic purposes. In addition, the indents of such embossing rollers rapidly become smeared by the soft aluminium strip embossed therewith and then have to be cleaned or renewed, which makes the process quite expensive.

The printing plate supports employed are plate formats made from rolled and embossed aluminium strip, as described in DE 199 02 527. The aluminium strip is embossed in the final rolling step using a roller which has a surface consisting of dome-shaped elevations. Due to the electrochemical roughening process to which the aluminium strip is subjected, the primarily embossed structure is retained for the most part, and the electrochemically produced fine structure is superimposed thereon. The additional electrochemical roughening is necessary in order to ensure firm anchoring of the recording layer and thus a long print run. If the printing plate supports are mechanically embossed and then anodized, the anchoring of the recording layer is inadequate, and consequently the print run is only about 30,000.

On imagewise exposure of the radiation-sensitive printing plate in a vacuum contact copy frame, the primary coarse structures in the aluminium support act as air extraction channels, and consequently the evacuation brings the mask rapidly into close contact with the printing plate. The nitrogen liberated from the quinone diazide or the diazonium salts of the radiation-sensitive recording layer during the exposure is also transported away rapidly, so that no nitrogen bubbles are able to form.

Part of the present object is also to provide a process for the production of the printing plate. A process of this type is distinguished by the fact that the rolled and embossed aluminium support, after pre-pickling and rinsing with water, is electrochemically roughened by means of alternating current in dilute hydrochloric acid, rinsed in water, desmutted in sulphuric acid, then rinsed and anodized, furthermore hydrophilized, dried and coated with a radiation-sensitive recording layer.

The further refinement of the process is described in claims 5 to 12.

The invention is explained in greater detail below with reference to examples.

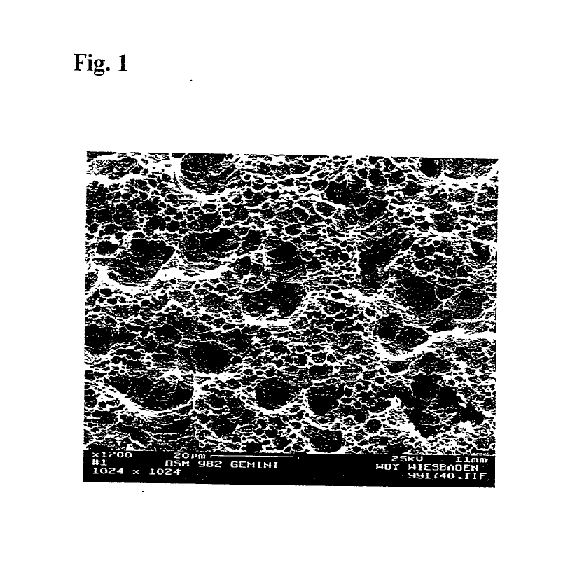

FIG. 1 shows an SEM photomicrograph of an embossed aluminium support surface having an average roughness Rₐ (on mechanical scanning in accordance with DIN 4768) of 0.63 μm, on which a fine structure generated by electrochemical roughening is superimposed, in accordance with Example 1 or 2,

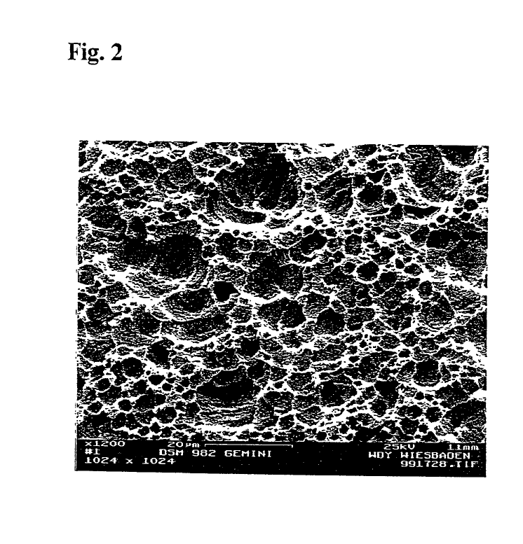

FIG. 2 shows an SEM photomicrograph of a pure aluminium support having a conventional mill finish surface, having an average roughness Rₐ=0.47 μm, in accordance with Comparative Example 1.

The basic material of the aluminium support of Examples 1 and 2 is a pure aluminium strip as employed for lithography purposes, which has been mechanically embossed by means of rollers by the process described in DE 199 02 527 A1. The surface structure of the embossed aluminium strip is determined by roughness measurement with mechanical scanning in accordance with DIN 4768 and, after electrochemical roughening of the embossed aluminium strip, by a scanning electron microscope (SEM) photomicrograph. The SEM photomicrographs are magnified 1200 times and recorded at a tilt angle of 400. The average roughness Rₐ in accordance with DIN 4768 of the embossed aluminium bands or aluminium supports is in the range from 0.63 μm to 0.82 μm.

Comparative Example 1 is a rolled pure aluminium strip, type AA 1050, with a thickness of 0.3 mm and a mill finish surface.

Examples according to the invention and comparative examples are compared with one another below and the advantages of the examples according to the invention are explained.

As a measure of the roughness and thus the capacity for transporting gas away, the Bekk smoothness is employed. Experience hitherto has shown that printing plates having Bekk smoothness values in the range from 30 to 200 sec give good evacuation behaviour.

### EXAMPLE 1

Pre-embossed aluminium plates are subjected to the following process steps analogously to DE 199 02 527:

pre-pickling in sodium hydroxide solution with from 10 to 100 g of sodium hydroxide/l of water at from 50 to 80° C. and a contact time of from 2 to 20 sec

rinsing with demineralized water for 10 sec alternating-current roughening in dilute hydrochloric acid (15 g/l) with a current strength of 40 A/dm² for 30 sec at 35° C.

rinsing with demineralized water for 10 sec

desmutting at 40° C. in sulphuric acid (200 g/1) for 20 sec

rinsing with demineralized water for 10 sec

anodization in sulphuric acid (100 g/l) with a current strength of 10 A/dm² at 35° C. for 30 sec

rinsing with demineralized water for 10 sec

hydrophilization in polyvinylphosphonic acid (10 g/l) at 40° C. for 10 sec

rinsing with demineralized water for 10 sec

drying at 120° C. for 60 sec

The formats are subsequently coated with a solution of a positive-working light-sensitive recording layer consisting of

| | |
|---|---|
| 5.00 pbw | of a cresol-formaldehyde novolak having a hydroxyl number |
| | of 420 in accordance with DIN 53783/53240 and an average |
| | molecular weight M_{w} of 10,000 (determined by GPC with |
| | polystyrene standard), |
| 1.20 pbw | of an ester made from 3 mol of 1,2-naphtoquinone-2- |
| | diazido-5-sulphonyl chloride and 1 mol of 2,3,4- |
| | trihydroxybenzophenone, |
| 0.15 pbw | of 1,2-naphtoquinone-2-diazido-4-sulphonyl chloride, |
| 0.05 pbw | of Victoria Pure Blue (C.I. 44045) and |
| 93.6 pbw | of a mixture (40/60) of methyl ethyl ketone and propylene |
| | glycol monomethyl ether |

and dried. The dry layer weight is 2 g/m². Bekk smoothness measurement on this sample gives the balue indicated in the table.

### EXAMPLE 2

The substrate produced in Example 1 is coated with a negative-working layer of the following solution consisting of

| | | |
|---|---|---|
| 81.590 | pbw | of an 8% strength butanone solution of the product of |
| | | the reaction of a polyvinylbutyral having a molecular |
| | | weight of from 70,000 to 80,000, which comprised 71% |
| | | by weight of vinylbutyral units, 2% by weight of vinyl |
| | | acetate units and 27% by weight of vinyl alcohol units, |
| | | with maleic anhydride (acid number of the product 40); |
| 0.510 | pbw | of a diazonium salt polycondensation product made from |
| | | 1 mol of 3-methoxydiphenylamine 4-diazoniumsulphate |
| | | and 1 mol of 4,4′-bismethoxymethyldiphenyl ether, |
| | | precipitated as mesitylenesulphonate |
| 0.070 | pbw | of Victoria Pure Blue FGA (C.I. Basic Blue 81) |
| 0.017 | pbw | of phenylazodiphenylamine |
| 0.060 | pbw | of phosphoric acid (85%) in |
| 61.800 | pbw | of methoxyethanol |
| 22.780 | pbw | of tetrahydrofuran |

with a dry layer weight of 1 g/m². Bekk smooothness measurement gives the value listed in the table.

### EXAMPLE 3

A pre-embossed aluminium strip is subjected to the following process steps in a strip unit:

Pre-Pickling:

in sodium hydroxide solution at from 50 to 80° C. with from 10 to 100 g/l of sodium hydroxide solution, with a contact time of from 2 to 20 sec.

Roughening:

in a mineral acid, such as hydrochloric or nitric acid, or a mixture thereof with sulphuric acid, with an acid concentration of from 5 to 30 g/l at a temperature of from 30 to 50° C., at a current density of from 30 to 200 A/dm², at a current contact time of from 3 to 30 sec, so that a charge flow of from 200 to 900 Cb/dm² results.

Intermediate Pickle:

consisting of sulphuric acid or phosphoric acid or a mixture thereof in the range from 50 to 300 g/l at a temperature of from 40 to 70° C. with a contact time of from 2 to 30 sec, or use of sodium hydroxide solution in the concentration range from 1 to 30 g/l at a temperature of from 20 to 70° C. with a contact time of from 2 to 20 sec.

Anodization:

in sulphuric or phosphoric acid or a mixture thereof at a concentration of from 50 to 300 g/1 at from 30 to 65° C. with a contact time of from 3 to 30 sec at a current density of from 20 to 100 A/dm².

Aftertreatment:

in an aqueous solution of polyvinylphosphonic acid having a content of from 0.5 to 10 g/l at from 40 to 80° C. with a contact time of from 3 to 20 sec.

Rinsing:

after each treatment step, rinsing is carried out with demineralized water for from 1 to 15 sec.

### COMPARATIVE EXAMPLE 1

Formats of pure aluminium strip (AA1050) having a normal mill finish surface as used for the production of conventional printing plates are subjected to the same process steps as in Example 1 and coated. Bekk smoothness measurement gives a significantly higher value than in Example 1 with the pre-embossed and electrochemically roughened aluminium support.

### COMPARATIVE EXAMPLE 2

The substrate described in Comparative Example 1 is coated with the solution indicated in Example 2 with a dry layer weight of 1 g/m². The Bekk smoothness is listed in the table.

### COMPARATIVE EXAMPLE 3

An aluminium plate pre-embossed analogously to DE 199 02 527 is anodized in sulphuric acid (100 g/l) at a current strength of 10 A/dm² at 35° C. for 30 sec and coated with the solution indicated in Example 1. On printing of the plates in accordance with Example 1 and Comparative Example 3, 5 times the number of prints are printed in a printing machine using the plate according to the invention than using the comparative plate, which is attributable to the fact that the recording layer of the plate in accordance with Example 1 is, as a consequence of the fine structure of the aluminium support, anchored significantly more firmly than in the coarse structure of the aluminium support of the plate in accordance with Comparative Example 3.

The following table shows the print runs and the Bekk smoothness values of the examples according to the invention and the comparative examples.

TABLE

| | Bekk smoothness in sec | Print run |
|---|---|---|
| Example 1 | 80 | 150,000 |
| Example 2 | 65 | 180,000 |
| Comparative Example 1 | 232 | 150,000 |
| Comparative Example 2 | 210 | 185,000 |
| Comparative Example 3 | 55 | 30,000 |

1. Printing plate having a radiation-sensitive recording layer on a rolled and embossed aluminium support which has a surface structure having pits which have an average diameter of from 10 to 60 μm, preferably from 20 to 24 μm, characterized in that a fine structure of indents having indent diameters in the range from 0.1 to 6 μm produced by electrochemical roughening is superimposed on this surface structure.

2. Printing plate according to claim 1, characterized in that the number of indents is from 18,000 to 200,000 per mm² with an area coverage of from 76 to 82%.

3. Printing plate according to claim 1 or 2, characterized in that the Bekk smoothness is from 30 to 200 sec.

4. Process for the production of a printing plate according to claims 1 to 3, characterized in that the rolled and embossed aluminium support, after pre-pickling and rinsing with water, is electrochemically roughened with alternating current in dilute hydrochloric acid, rinsed in water and desmutted in sulphuric acid, then rinsed and anodized, furthermore hydrophilized, dried, if necessary formatted and coated with a radiation-sensitive recording layer.

5. Process according to claim 4, characterized in that the aluminium support is electrochemically roughened in hydrochloric or nitric acid or a mixture thereof with sulphuric acid, with an acid concentration of from 5 to 30 g of acid/l of water, at a temperature of from 30 to 50° C., at a current density of from 30 to 200 A/dm² and a current contact time of from 3 to 30 sec with a charge flow of from 200 to 900 Cb/dm².

6. Process according to claim 5, characterized in that the electrochemical roughening is carried out in an aqueous hydrochloric acid solution with a concentration of from 10 to 20 g of hydrochloric acid/l of water with an alternating current having a current strength of from 35 to 45 A/dm², at a hydrochloric acid solution temperature of from 30 to 45° C. for a period of 30 sec.

7. Process according to claim 4 or 5, characterized in that the rolled and embossed aluminium support is, before the electrochemical roughening, chemically pre-pickled in aqueous sodium hydroxide solution with a concentration of from 10 to 100 g of sodium hydroxide/l of water at a sodium hydroxide solution temperature of from 50 to 80° C. for from 5 to 20 sec and then rinsed with demineralized water for from 1 to 15 sec.

8. Process according to claim 4, characterized in that the rolled and embossed aluminium support is, after the electrochemical roughening, subjected to intermediate pickling with sulphuric acid or phosphoric acid or a mixture thereof, with an acid concentration of from 50 to 300 g of acid/l of water, at a temperature of from 40 to 70° C. and a contact time of from 2 to 30 sec.

9. Process according to claim 4, characterized in that the rolled and embossed aluminium support is, after the electrochemical roughening, subjected to intermediate pickling with sodium hydroxide solution, with a concentration of from 1 to 30 g of hydroxide/l of water, at a temperature of from 20 to 70° C. and a contact time of from 2 to 20 sec.

10. Process according to claim 4, characterized in that the rolled and embossed aluminium support is, after the electrochemical roughening, rinsed with demineralized water for from 1 to 15 sec and desmutted in a sulphuric acid solution with from 100 to 200 g of sulphuric acid/l of water at a temperature of from 35 to 65° C. for from 5 to 25 sec and then rinsed again with demineralized water for from 3 to 12 sec.

11. Process according to claim 4, characterized in that the aluminium support is anodized in sulphuric or phosphoric acid or a mixture thereof, with a concentration of from 50 to 300 g of acid/l of water, at a temperature of from 30 to 65° C. and a contact time of from 3 to 30 sec at a current density of from 20 to 100 A/dm².

12. Process according to claim 4, characterized in that the aluminium support is anodized in aqueous sulphuric acid with a concentration of from 100 to 200 g of sulphuric acid/l of water with a current strength of 10 A/dm² of an alternating current, at a sulphuric acid solution temperature of from 30 to 45° C. for 30 sec.

13. Process according to claim 4, characterized in that the aluminium support is hydrophilized in aqueous polyvinylphosphonic acid with a concentration of from 0.5 to 10 g of acid/l of water and a temperature of from 40 to 80° C. for from 3 to 20 sec, and in that rinsing with demineralized water is carried out for from 1 to 15 sec both before and after the hydrophilization.

14. Process according to claim 4, characterized in that the hydrophilized aluminium support is dried at from 90 to 130° C. for a period of from 1 to 15 sec, and a radiation-sensitive, positive- or negative-working recording layer which, when dried, has a dry layer weight of from 2 g/m² or 1 g/m² is then applied.

15. Process according to claim 14, characterized in that the positive-working recording layer comprises

| | |
|---|---|
| 5.00 pbw | of a cresol-formaldehyde novolak having a hydroxyl |
| | number of 420 in accordance with DIN 53783/53240 and |
| | an average molecular weight M_{w} of 10,000 (determined by |
| | GPC with polystyrene standard), |
| 1.20 pbw | of an ester made from 3 mol of 1,2-naphtoquinone-2- |
| | diazido-5-sulphonyl chloride and 1 mol of 2,3,4-tri- |
| | hydroxybenzophenone, |
| 0.15 pbw | of 1,2-naphtoquinone-2-diazido-4-sulphonyl chloride, |
| 0.05 pbw | of Victoria Pure Blue (C.I. 44045) and |
| 93.6 pbw | of a mixture of methyl ethyl ketone and propylene |
| | glycol monomethyl ether (40/60), |

where pbw denotes parts by weight.

16. Process according to claim 14, characterized in that the negative-working recording layer comprises

| | | |
|---|---|---|
| 81.590 | pbw | of an 8% strength butanone solution of the product |
| | | of the reaction of a polyvinylbutyral having a |
| | | molecular weight of from 70,000 to 80,000 which |
| | | comprised 71% by weight of vinylbutyral units, 2% by |
| | | weight of vinyl acetate units and 27% by weight of |
| | | vinyl alcohol units, with maleic anhydride (acid |
| | | number of the product 40); |
| 0.510 | pbw | of a diazonium salt polycondensation product made |
| | | from 1 mol of 3-methoxydiphenylamine 4-diazonium- |
| | | sulphate and 1 mol of 4,4′-bismethoxymethyldiphenyl |
| | | ether, precipitated as mesitylenesulphonate |
| 0.070 | pbw | of Victoria Pure Blue FGA (C.I. Basic Blue 81) |
| 0.017 | pbw | of phenylazodiphenylamine |
| 0.060 | pbw | of phosphoric acid (85%) in |
| 61.800 | pbw | of methoxyethanol |
| 22.780 | pbw | of tetrahydrofuran, |
